(19) United States
(12) Patent Application Publication
(10) Pub. No.: US 2007/0138489 A1
(43) Pub. Date: Jun. 21, 2007

(54) SEMICONDUCTOR LIGHT-EMITTING DEVICE AND A METHOD OF FABRICATING THE SAME

(76) Inventors: Stewart Edward Hooper, Oxford (GB); Valerie Bousquet, Oxford (GB)

Correspondence Address: MARK D. SARALINO (GENERAL);RENNER, OTTO, BOISSELLE & SKLAR, LLP, 1621 EUCLID AVENUE, NINETEENTH FLOOR, CLEVELAND, OH, 44115-2191, US

(21) Appl. No.: 11/562,141

(22) Filed: Nov. 21, 2006

(30) Foreign Application Priority Data
Nov. 25, 2005 (GB) 0524013.0

(51) Int. Cl. H01L 33/00

(52) U.S. Cl. 257/94

(57) ABSTRACT

A semiconductor light-emitting device is fabricated in a nitride materials system and has an active region comprising two or more quantum well layers. Each quantum well layer is separated from a neighbouring quantum well layer by a respective barrier layer. The or each barrier layer has a thickness that is at least 13 times as great as the thickness of any one of the quantum well layers. This increases the output power of the device.

This Nonprovisional application claims priority under 35 U.S.C. § 119(a) on British Patent Application No. 0524013.0 filed in U.K. on Nov. 25, 2005, the entire contents of which are hereby incorporated by reference.

### FIELD OF THE INVENTION

The present invention relates to a semiconductor light-emitting device, and in particular to a semiconductor light-emitting device fabricated in a nitride materials system such as, for example, the (Al, Ga, In)N materials system. The invention may be applied to, for example, a semiconductor laser diode (LD) or light-emitting diode LED).

### BACKGROUND OF THE INVENTION

The (Al, Ga, In)N material system includes materials having the general formula AlₓGa_{y}In1_{-x-y}N where 0≦x≦1 and 0≦y≦1. In this application, a member of the (Al, Ga, In)N material system that has non-zero mole fractions of aluminum, gallium and indium will be referred to as AlGaInN, a member that has a zero aluminum mole fraction but that has non-zero mole fractions of gallium and indium will be referred to as InGaN, a member that has a zero indium mole fraction but that has non-zero mole fractions of gallium and aluminum will be referred to as AlGaN, and so on. There is currently considerable interest in fabricating semiconductor light-emitting devices in the (Al, Ga, In)N material system since devices fabricated in this system can emit light in the blue-violet wavelength range of the spectrum (corresponding to wavelengths in the range of approximately 380-450 nm).

Semiconductor light-emitting devices fabricated in the (Al, Ga, In)N materials system are described, for example, by S. Nakamura et al in “Jap. J. Appl. Phys.” Vol. 35, ppL74-L76 (1996). They are also described in U.S. Pat. No. 5,777,350, which teaches use of the metal-organic chemical vapour deposition (MOCVD) growth technique to fabricate light-emitting devices in the (Al, Ga, In)N materials system. MOCVD (also known as metal-organic vapour phase epitaxy or MOVPE) takes place in an apparatus which is commonly at atmospheric pressure but sometimes at a slightly reduced pressure of typically about 10 kPa. Ammonia and the species providing one or more Group III elements to be used in epitaxial growth are supplied substantially parallel to the surface of a substrate upon which epitaxial growth is to take place, thus forming a boundary layer adjacent to and flowing across the substrate surface. It is in this gaseous boundary layer that decomposition to form nitrogen and the other elements to be epitaxially deposited takes place so that the epitaxial growth is driven by gas phase equilibria.

Another known semiconductor growth technique is molecular beam epitaxy (MBE). In contrast to MOCVD, MBE is carried out in a high vacuum environment. In the case of MBE as applied to the (Al, In, Ga)N system, a high or ultra-high vacuum (UHV) environment, typically around 1×10⁻³ Pa, is used. A nitrogen precursor is supplied to the MBE chamber by means of a supply conduit and species providing aluminum, gallium and/or indium, and possibly also a suitable dopant species, are supplied from appropriate sources within heated effusion cells fitted with controllable shutters to control the amounts of the species supplied into the MBE chamber during the epitaxial growth period. The shutter-control outlets from the effusion cells and the nitrogen supply conduit face the surface of the substrate upon which epitaxial growth is to take place. The nitrogen precursor and the species supplied from the effusion cells travel across the MBE chamber and reach the substrate where epitaxial growth takes place in a manner which is driven by the deposition kinetics.

At present, the majority of growth of high quality nitride semiconductor layers is carried out using the MOCVD process. The MOCVD process allows growth to occur at a V/III ratio well in excess of 1000:1. The V/III ratio is the molar ratio of the group V element to the Group III element during the growth process. A high V/III ratio is preferable during the growth of a nitride semiconductor material, since this allows a higher substrate temperature to be used which in turn leads to a higher quality semiconductor layer.

FIG. 1 is a schematic view of a semiconductor laser device or laser diode (LD) fabricated in the (Al, Ga, In)N material system. The device is able to emit light in the blue wavelength range, in the 380 nm to 450 nm wavelength range. The device is described in UK patent application No. 0325099.0.

The laser diode 18 of FIG. 1 is grown over a substrate 1. In the laser diode 18 of FIG. 1 the substrate 1 is a template substrate consisting of an n-type doped GaN layer 3 grown over a sapphire base substrate 2. A buffer layer 4, a first cladding layer 5 and a first optical guiding layer are grown, in this order, over the substrate 1. In the embodiment of FIG. 1 the buffer layer 4 is a n-type GaN layer, the first cladding layer 5 is an n-type AlGaN layer, and the first optical guiding layer is an n-type GaN layer.

An active region 7 is grown over the first optical guiding layer 6.

A second optical guiding layer 8, a second cladding layer 9 and a cap layer 10 are grown, in this order, over the active region 7. The second optical guiding layer 8 and second cladding layer 9 have opposite conductivity type to the first optical guiding layer 6 and first cladding layer 5. In the laser diode 18 of FIG. 1 the second optical guiding layer 8 is a p-type GaN layer, the second cladding layer 9 is a p-type AlGaN layer, and the cap layer 10 is a p-type GaN layer.

The active region 7 of the laser device 18 shown in FIG. 1 is a multiple quantum well (MQW) active region, and contains a plurality of quantum well layers 12, 14, 16. Each quantum well layer 12, 14, 16 is sandwiched between two barrier layers 11, 13, 15, 17. In the laser device 18 of FIG. 1, the lowermost barrier layer 11 and the uppermost barrier layer 17 are AlGaN layers. The intermediate barrier layers 13, 15 may be, for example, layers of InₓGa₁₋ₓN (0≦x≦0.05), AlₓGa₁₋ₓN (0≦x≦0.4) or AlGaInN. The quantum well layers 12, 14, 16 may be, for example, layers of In, Ga₁₋ₓN (0≦x≦0.3), AlₓGa₁₋ₓN (0≦x≦0.1) or AlGaInN.

Other examples of structures for a semiconductor laser device fabricated in the (Al, Ga, In)N material system, or of methods of fabricating such devices, are described in UK patent application Nos. 0104598.8, 0219729.1, 0325098.2 and 0325100.6, in Electronics Letters Vol. 40 No. 1, p33 (2004), in Electronics Letters Vol. 41 No. 13, p739 (2005), in J. Cryst. Growth Vol. 278 p361 (2005), and in Applied Physics Letters Vol. 86 p192105-3 (2005).

JP-2001 044 570

discloses a semiconductor laser device fabricated in the AlGaN/InGaN materials system. The active layer of the laser has a multiple quantum well structure in which the well layers alternate with barrier layers, and the English abstract teaches that the ratio between the thickness of a well layer and the thickness of a barrier layer is preferably 1:3 to 1:10, and is more preferably between 1:4 and 1:7.

WO 2005/011007 relates to a light-emitting diode fabricated in the (Al, In, Ga)N materials system. The active layer consists of well layers of 2 nm thickness separated by barrier layers having a thickness of 18 nm, corresponding to a ratio of barrier layer thickness: quantum well thickness of 9:1.

EP 1 313 187 and WO02/05399 disclose a laser device fabricated in the (Al, In, Ga)N materials systems. The active region consists of seven barrier layers having a thickness of 250 Å stacked with 6 well layers having a thickness of 30 Å, corresponding to a ratio of barrier layer thickness: quantum well layer thickness of 8.3:1.

US 2005/0236642 and WO2004/008551 disclose a light-emitting diode fabricated in the (Al, Ga, In)N material system. The active region is formed of InGaN well layers having a thickness of 1.5 nm and barrier layers with a thickness of 12 nm, corresponding to a ratio of barrier layer thickness: quantum well layer thickness of 8:1.

### SUMMARY OF THE INVENTION

The present invention provides a semiconductor light-emitting device fabricated in a nitride materials system and having an active region comprising two or more quantum well layers, the or each pair of neighbouring quantum well layers being separated from one another by a respective barrier layer; wherein the or each barrier layer has a thickness that is at least 13 times as great as the thickness of any one of the quantum well layers.

Making the or each barrier layer of a multiple quantum well (MQW) active region with a thickness that is at least 8 times as great as the thickness of any one of the quantum well layers of the active region increases the optical efficiency of the MQW active region, and thereby results in a light-emitting device having a greater output intensity. In contrast, existing blue LEDs and violet LDs grown by MOVPE currently have MQW active regions in which the ratio of the thickness of the barrier layer to the thickness of the quantum well layers is between 2:1 and 3:1.

Since the or each barrier layer has a thickness that is at least 8 times as great as the thickness of any one of the quantum well layers, the barrier layers in a device according to the present invention are thicker than the barrier layers in conventional device. This provides a further advantage, since the thicker barrier layers are effective at protecting the quantum well layers if high temperature annealing stages are used during growth of the active region. As an example of this advantage, InGaN layers are often used as quantum well layers in a device fabricated in the (Al, Ga, In)N system, but InGaN is prone to decompose during a high-temperature annealing step. When the present invention is used in a light-emitting device fabricated in the (Al, Ga, In)N system, the thicker barrier layers used in the present invention will prevent decomposition of InGaN quantum well layers during an annealing step. This allows an annealing step with a longer duration and/or a higher annealing temperature to be used.

The semiconductor light-emitting device may be fabricated in the (Al, Ga, In)N materials system whereby each quantum well layer may be an (Al, Ga, In)N layer and the or each barrier layer may be an (Al, Ga, In)N layer.

Each quantum well layer may be an InGaN layer.

The or each barrier layer may be an InGaN layer. The indium mole fraction of the or each barrier layer may be less than the indium mole fraction of each quantum well layer.

Alternatively, the or each barrier layer may be a GaN layer.

The or each barrier layer may have a thickness that is up to 30 times as great as the thickness of any one of the quantum well layers.

Each quantum well layer may have a thickness of from 1 nm to 20 nm.

The or each barrier layer may have a thickness of from 8 nm to 50 nm.

Each quantum well layer may be doped.

The or each barrier layer may be doped.

The device may comprise a semiconductor laser device, or it may comprise a semiconductor light-emitting diode.

A second aspect of the invention provides a method of fabricating a semiconductor light-emitting device in a nitride materials system, the method comprising the steps of: a) growing a first quantum well layer; b) growing a first barrier layer over the first quantum well layer; and c) growing a second quantum well layer over the first barrier layer; wherein the first barrier layer has a thickness that is at least 13 times as great as the thickness of any one of the quantum well layers.

The method may further comprise: d) growing a second barrier layer over the second quantum well layer; and e) growing a third quantum well layer over the second barrier layer; wherein the second barrier layer has a thickness that is at least 13 times as great as the thickness of any one of the quantum well layers.

The method may further comprise annealing the first barrier layer before step (c) of growing the second quantum well layer.

The method may further comprise annealing the second barrier layer before step (e) of growing the third quantum well layer.

Some quantum well layers such as, for example, InGaN quantum well layers are prone to decomposition during an annealing step, and it has hitherto been necessary to use short annealing times and low annealing temperatures to prevent decomposition of the quantum well layers. The invention provides a further advantage since the thicker barrier layers of the invention prevent thermal decomposition of quantum well layer(s) during an annealing step by “sealing” the quantum well layers. For example, an annealing time of 2 minutes has been found to have no adverse effects when the ratio of the barrier layer thickness: quantum well thickness is 13:1 or greater, and it is expected that an annealing time of up to 15 minutes could be used without having any adverse effect on a quantum well layer when the ratio of the barrier layer thickness: quantum well thickness is 13:1 or greater.

### BRIEF DESCRIPTION OF THE DRAWINGS

Preferred embodiments of the present invention will now be described by way of illustrative example with reference to the accompanying figures in which:

FIG. 1 is a schematic sectional view of a semiconductor laser device;

FIG. 2 is a schematic sectional view of an active region according to the present invention for a semiconductor light-emitting device; and

FIG. 3 shows the dependence of output power against the ratio of the thickness of a barrier layer to the thickness of a quantum well layer.

### DESCRIPTION OF THE EMBODIMENTS

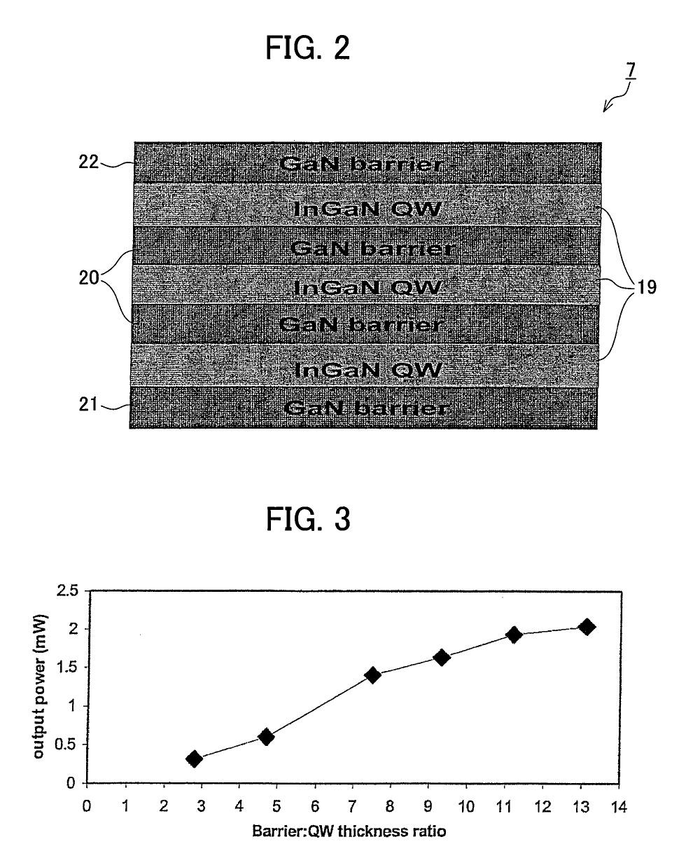

FIG. 2 is a schematic sectional view of an active region 7′ of a semiconductor light-emitting device according to the present invention. The active region 7′ contains a plurality of quantum well layers 19. FIG. 2 shows an active region 7′ having 3 quantum well layers 19, but an active region of the invention may have only 2 quantum well layers or may have more than 3 quantum well layers.

Each quantum well layer 19 is separated from a neighbouring quantum well layer 19 by a barrier layer 20. These barrier layers will be referred to as “intermediate” barrier layers, to distinguish them from the lower and upper barrier layers shown as layers 21, 22 in FIG. 2. The lower barrier layer 21 will, in the complete device structure, be disposed between the lowest quantum well layer of the active region and a lower cladding layer or optical guiding layer, and the upper barrier layer 22 will, in the complete device structure, be disposed between the uppermost quantum well layer of the active region and an upper cladding layer or optical guiding layer. The lower and upper barrier layers may alternatively be omitted from the active region.

An active region of the present invention is fabricated in a nitride material system such as, for example, the (Al, Ga, In)N materials system. By specifying that a device (or part thereof) is fabricated in a particular materials system, it is meant that each epitaxially-grown semiconductor layer of the device (or of the part thereof) is made of a material that belongs to the specified materials system. Thus, in specifying that the active region of FIG. 2 is fabricated in, as an example, the (Al, Ga, In)N materials system it is meant that the quantum well layers and intermediate barrier layers shown in FIG. 2 are formed of materials that are members of the (Al, Ga, In)N materials systems.

In embodiments in which the active region 7 of FIG. 2 is fabricated in the (Al, Ga, In)N materials system, the quantum well layers 19 may be, for example, layers of InₓGa_{1-N} (0≦x≦0.3). Alternatively, the quantum well layers 19 may be formed of AlGaN or AlGaInN. The intermediate barrier layers 20 may be formed of, for example, GaN, or In_{y}Ga_{1-y}N where y<x and, for example, 0≦y≦0.05. Alternatively, the intermediate barrier layers 20 may be formed of AlGaN or AlGaInN.

According to the present invention, the thicknesses of the quantum well layers 19 and the intermediate barrier layers 20 are chosen such that the thickness of an intermediate barrier layer 20 is at least 13 times as great as the thickness of a quantum well layer 19.

The thicknesses of the upper and lower barrier layers 21, 22 of FIG. 2 are preferably also at least 13 times greater than the thickness of a quantum well layer 10. The upper and lower barrier layers 21, 22 may have the same composition as the intermediate barrier layers 20, or they may have a different composition from the intermediate barrier layers, for example as taught in UK patent application No. 0325099.0. In embodiments in which the active region 7 of FIG. 2 is fabricated in the (Al, Ga, In)N materials system, the upper and lower barrier layers 21, 22 are typically formed of AlGaN.

In a practical semiconductor light-emitting device, it is likely that the quantum well layers 19 of the active region would be grown to have the same nominal thickness as one another, since variations in the quantum well layer thickness from one quantum well layer to another would lead to variations in the optical properties of each quantum well layer. In a practical semiconductor light-emitting device which has two or more intermediate barrier layers 20, the intermediate barrier layers are preferably grown to have the same nominal thickness as one another (although, in principle, the intermediate barrier layers could be grown to have different nominal thicknesses from one another).

In currently available nitride light-emitting devices, the ratio between the thickness of an intermediate barrier layer and the thickness of a quantum well layer is between 2:1 and 3:1. The highest reported ratio for the thickness of an intermediate barrier layer to the thickness of a quantum well layer in a nitride light-emitting device is 5:1, given in Applied Physics Letters Vol. 86 p192105-3 (2005). It can therefore be seen that the ratio of the barrier layer thickness to the quantum well layer thickness is substantially greater in an active region of the present invention than in the prior art devices.

FIG. 3 shows the optical output power of a nitride semiconductor light-emitting device as a function of the ratio of the thickness of a barrier layer of the active region to the thickness of a quantum well layer. The results were obtained for a nitride LED having a multiple quantum well active layer, but similar results would be obtained for a laser diode fabricated in a nitride materials system. As can be seen, increasing the ratio between the thickness of an intermediate barrier layer to the thickness of a quantum well layer provides a significant increase in the output optical power of the device. For a thickness ratio of 2:1-3:1, as used in the currently-available nitride semi-conductor laser diodes and light-emitting diodes, the optical output power obtained is around 0.3 mW. Increasing the ratio of the barrier layer thickness to the quantum well layer thickness to 13:1 or above increases the optical output power to around 2 mW, and further increasing the ratio between the barrier layer thickness and the quantum well layer thickness would be expected to provide a further increase in the optical output power or at least maintain the power output at approximately 2 mW.

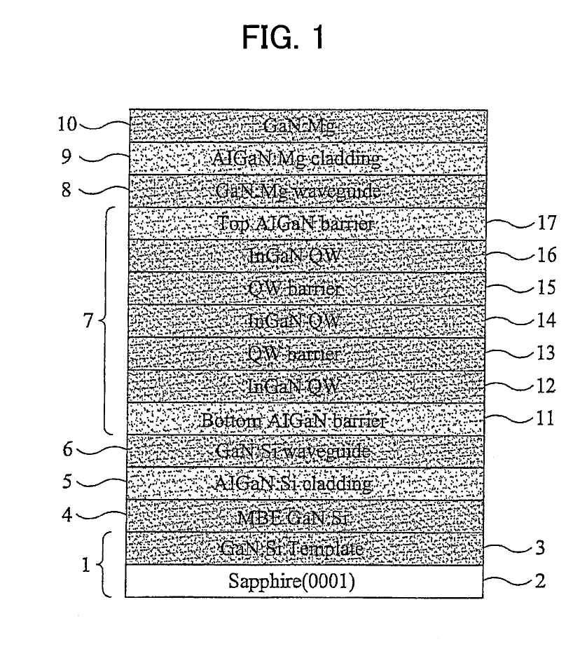

The results of FIG. 3 were obtained using a series of semiconductor layer structures, each of which similar to that shown in FIG. 1 but with the cladding layers 5, 9 and the optical guiding layers 6,8 omitted. The quantum well layers 12, 14, 16 were formed of InGaN with an indium mole fraction of approximately 10%, the intermediate barrier layers 13, 15 were formed of GaN, and the upper and lower barrier layers 11, 17 were formed of AlGaN with an aluminum mole fraction of approximately 12%. The LED driving current was 20 mA d.c. The thickness of the quantum well layers was 2 nm in each of the structures, whereas the thickness of the barrier layers was varied from one structure to another so as to obtain structures having the ratios of the quantum well layer thickness to the barrier layer thickness shown in FIG. 3.

Furthermore, the ratio of the intermediate barrier layer thickness to the quantum well layer thickness is preferably chosen to be less than 30:1. As the thickness of a barrier is increased the time taken to grow the barrier layer is also increased, and a barrier layer with a thickness of 50 nm would take over an hour to grow by MBE. A ratio of the intermediate barrier layer thickness to the quantum well layer thickness of 30:1 therefore generally represents a practical limit to the barrier layer thickness, since use of thicker barrier layers would lead to very long growth times.

Moreover, as can be seen from FIG. 3, the curve of the output power against the ratio of the intermediate barrier layer thickness to the quantum well layer thickness is flattening out as the ratio approaches 15, and may possibly even start to decrease once the ratio increases significantly above 15. Use of a ratio that is substantially greater than 15 may therefore provide little increase in output power and, in such cases, the ratio is preferably less than 15:1. (More generally, in a case where the output power reaches a maximum for a particular value of the ratio of the intermediate barrier layer thickness to the quantum well layer thickness, the ratio may be chosen to have the value that provides the greatest output power, or a value close to the value that provides the greatest output power.)

The present invention may in principle be applied to an active region in which each quantum well layer has a thickness in the range from 1 nm to 20 nm. It should, however, be noted that applying the invention to a active region having a quantum well layer thickness of 20nm would lead to an intermediate barrier layer having a thickness of at least 260 nm, and an intermediate barrier layer having such a thickness can be undesirable. In a preferred embodiment, therefore, the thickness of each intermediate barrier layer 20 is in the range from 8 nm to 50 nm—which allows the invention to be applied to an active region in which the quantum well layer thickness may be up to 3.85 nm.

An active region 7′ of the present invention may be incorporated in a semiconductor laser diode fabricated in a nitride materials system such as, for example, the (Al, Ga, In)N materials system. For example, the active region 7 of the laser diode shown in FIG. 1 may be replaced by an active region according to the present invention.

An active region of the present invention may also be incorporated in an LED fabricated in a nitride materials system such as, (for example, the (Al, Ga, In)N materials system. A suitable LED structure to which the present invention could be applied may consist of, for example, the structure shown in FIG. 1 but with the cladding layers 5, 9 and the optical guiding layers 6, 8 omitted.

The quantum well layers 19, the intermediate barrier layers 20, and the lower and upper barrier layers 21, 22 of an active region of the present invention may be undoped. Alternatively, the quantum well layers 19 and/or the intermediate barrier layers 20 may be intentionally doped. In an embodiment in which the active region is fabricated in the (Al, Ga, In)N materials system or another nitride materials systems, a suitable n-type dopant is, for example silicon and a suitable p-type dopant is, for example, magnesium. The lower and upper barrier layers 21, 22 may also be doped.

In one preferred embodiment, the quantum well layers 19 are 2 nm thick layers of InGaN with an indium mole fraction of approximately 10%, and the intermediate barrier layers 20 are 26 nm or 28 nm thick GaN layers. This embodiment provides a ratio for the intermediate barrier layer thickness to the quantum well layer thickness of 13:1 or 14:1 respectively.

The invention may be applied to light-emitting devices grown by MBE or by MOCVD. As one example, a device according to the present invention may be grown by a method as described in UK patent publication No. 2 407 701.

As explained above, a light-emitting device of the present invention has a greater optical output power than a conventional device having a smaller ratio of intermediate barrier layer thickness to quantum well layer thickness. A device according to the present invention does, however, have a further advantage, which is that, for a given thickness of quantum well layer, the intermediate barrier layers in an active region of the invention are thicker than the barrier layers in a conventional device, and these thicker barrier layers are useful in protecting the quantum well layers if the structure is annealed during the growth process.

As is known, it is often necessary or desirable for the fabrication of a semiconductor layer structure to include one or more steps of high-temperature annealing of the layer structure. As an example, UK Patent Application No. 0325099.0 describes a fabrication method for a nitride semiconductor device in which the step of growing each intermediate barrier layer is immediately followed by an annealing step. One problem encountered in growth methods that involve an annealing step is that some semiconductor materials are prone to decompose at high temperatures and this can restrict an annealing step, for example by requiring that an annealing step is carried out at a lower temperature than desired and, or has a shorter duration that desired. In particular, InGaN is prone to decomposition during an annealing step. The present invention allows higher annealing temperatures to be used and/or longer annealing times to be used, since the thicker barrier layers present in an active region of the invention protect the quantum well layers during the annealing step. The thicker barrier layers of the invention prevent thermal decomposition of the quantum well layers during the annealing step by “sealing” the quantum well layers. In tests, an annealing time of 2 minutes at an annealing temperature of 920° C. was found to have no adverse effect on 2 nm thick InGaN quantum wells sandwiched between 26 nm thick GaN barrier layers, and it is expected that an annealing time of up to 15 minutes could be used without having any significant adverse effect on 2 nm thick InGaN quantum wells sandwiched between 26 nm thick GaN barrier layers. It was also found that an annealing temperature of 950° C. could be used with 26 nm thick GaN barrier layers without having any adverse effect on the InGaN quantum well layers (although increasing the annealing temperature from 920° C. to 950° C. did not produce any significant increase in the power output of the resultant laser structure).

A method suitable for fabricating a device of the invention will now be described with reference to fabrication of a laser device having the structure shown in FIG. 1. The fabrication method will be described with reference to an MBE (molecular beam epitaxy) growth process, although other growth techniques can be used. The invention will be described with reference to fabrication of a laser device in the (Al, Ga, In)N materials system.

Initially, a suitable substrate is cleaned and prepared. In the embodiment of FIG. 1 the device has a template substrate 1 consisting of an n-type doped GaN epitaxial layer 3 grown over a sapphire base 2, but the device is not limited to use with this particular substrate. The cleaned and prepared substrate is then introduced into the growth chamber of an MBE growth apparatus.

Semiconductor layers that include at least a barrier layer 11 disposed over a first cladding layer 5 are then grown over the substrate 1 in a first growth step. To grow the specific device structure of FIG. 1, a buffer layer 4 (in this example an n-type doped GaN layer), a first cladding layer 5 (in this example an n-type doped AlGaN layer) and a first optical guiding layer 6 (in this example an n-type doped GaN layer) are grown, in this order, over the substrate 1 although the invention is not limited to this specific layer structure. The growth of these layers is conventional, and a growth temperature of approximately 900° C. may be used.

A first AlGaN barrier layer 11 having an aluminum mole fraction of approximately 12% then is grown on the first optical guiding layer 6. The first barrier layer 1 1 is grown to have a thickness that is at least 13 times as great as the intended thickness of the quantum well layers 12, 14, 16. If, as an example, the intended thickness of the quantum well layers 12, 14, 16 is 2 nm, the first barrier layer 11 is grown to have a thickness that is at least 26 nm. A growth temperature of approximately 650° C. may be used for the first barrier layer 11

The deposition of material is then stopped, and the temperature in the growth chamber is increased so as to anneal the first barrier layer 11 at an annealing temperature that is greater than the growth temperature of the first barrier layer. The growth temperature in an MBE apparatus may for example be determined by a heated susceptor on which the substrate 1 is mounted, and the substrate temperature is varied by varying the susceptor temperature. Alternatively, the substrate may be directly heated by radiation from a heater element provided in the growth chamber, and the substrate temperature can be varied by increasing or decreasing the output of the heater.

The duration of the annealing step will depend on the annealing temperature. If a low annealing temperature is used the duration of the annealing step will in general be relatively long, whereas if a high annealing temperature is used the duration of the annealing step may be relatively short. The annealing temperature of a barrier layer should be at least 50° C. greater than the growth temperature of that layer although, in practice, best results are obtained using an annealing temperature that is 200° C. or more higher than the growth temperature of the barrier layer. In the case of a barrier layer 11 grown at a growth temperature of approximately 650° C., good results were obtained by annealing the barrier layer at an annealing temperature of approximately 900° C. for 20 seconds, although longer annealing times may be used.

It should be noted that the rate at which the substrate temperature is increased to a desired annealing temperature and the rate at which the substrate temperature is reduced after an annealing step should be kept sufficiently low to avoid inducing significant thermal stresses in the substrate or in the layers grown over the substrate. A temperature ramp rate of no more than 40° C./minute has been found to be suitable. Thus, even though the annealing step in the example given above has a duration of 20 seconds, it will take approximately 10 minutes to increase the substrate temperature from the growth temperature of 650° C. to the annealing temperature of 900° C., and approximately a further 10 minutes after the annealing step to reduce the substrate temperature to a suitable temperature for the growth of the next layer.

Once the first barrier layer 11 has been annealed, the deposition of material is resumed. In a second growth step a first quantum well layer 12 is grown on the first barrier layer 11 after which another barrier layer 13 is grown on the first quantum well layer. In this embodiment, the first quantum well layer 12 was a 2 nm thick InGaN layer with an indium mole fraction of approximately 10%, and the barrier layer 13 was a GaN layer with a thickness of at least 26 nm. The barrier layer 13 will be referred to as an “intermediate” barrier layer since, in the completed structure, it is disposed between two quantum well layers, as will be described below. In general, after the first barrier layer 11 has been annealed the temperature of the growth chamber will be reduced before the first quantum well layer 12 is grown—in this embodiment, a suitable growth temperature for the first quantum well layer 12 and the barrier layer 13 is approximately 650° C.

The deposition of material is then stopped, and the temperature in the growth chamber is increased so as to anneal the intermediate barrier layer 13 at an annealing temperature that is greater than its growth temperature. The temperature and duration of this annealing step may correspond to those described above for the step of annealing the lower AlGaN barrier layer 11, although since the thick intermediate barrier layer 13 protects the first quantum well layer 12 during the annealing step a longer annealing time and/or a higher annealing temperature may be used without adversely affecting the first quantum well layer 12.

Once the intermediate barrier layer 13 has been annealed, the deposition of material is resumed. (In general, the growth chamber temperature will be reduced after the annealing step, before further layers are grown.) In a third growth step an InGaN second quantum well layer 14 is grown on the intermediate barrier layer 13 after which a further intermediate GaN barrier layer 15 is grown on the second quantum well layer. The structure and growth conditions of the second quantum well layer 14 and the further intermediate barrier layer 15 correspond to the structure and growth conditions of the first quantum well layer 12 and the intermediate barrier layer 13.

The deposition of material is then stopped, and the temperature in the growth chamber is increased so as to anneal the second intermediate barrier layer 15 at an annealing temperature that is greater than its growth temperature. The temperature and duration of this annealing step correspond to those described above for the step of annealing the lower AlGaN barrier layer 11.

Once the second intermediate barrier layer 15 has been annealed, the deposition of material is resumed. (In general, the growth chamber temperature will be reduced after the annealing step, before further layers are grown.) In a fourth growth step a third InGaN quantum well layer 16 is grown on the barrier layer 15. A final AlGaN barrier layer 17 is then grown on the third quantum well layer 16, to complete the active region 7. The structure and growth conditions of the third quantum well layer 16 and the final barrier layer 17 correspond to the structure and growth conditions of the first quantum well layer 12 and the first barrier layer 11.

In this embodiment the intermediate barrier layers 13, 15, and preferably the first and final barrier layers 11, 17, are grown to have a thickness that is at least 13 times as great as the thickness of the quantum well layers 12, 14, 16. If the quantum well layers 12, 14, 16 each have a thickness of 2 nm, the intermediate barrier layers 13, 15, and preferably the first and final barrier layers 11, 17, each have a thickness of 26 nm or greater.

The deposition of material is then stopped, and the temperature in the growth chamber is increased so as to anneal the final barrier layer 17 at an annealing temperature that is greater than its growth temperature. The temperature and duration of this annealing step correspond to those described above for the step of annealing the lower AlGaN barrier layer 11.

Finally, the deposition of material is again resumed. A second optical guiding region 8 (in this example a p-type doped GaN layer), a second cladding region 9 (in this example a p-type doped AlGaN layer), and a cap layer 10 (in this example a p-type doped GaN layer) are grown, in this order, over the final barrier layer 17 to provide the laser structure shown in FIG. 1. A growth temperature of approximately 970° C. is suitable for the p-type layers 8, 9, 10.

What is claimed is:

1. A semiconductor light-emitting device fabricated in a nitride materials system and having an active region comprising two or more quantum well layers, each quantum well layer being separated from a neighbouring quantum well layer by a respective barrier layer;
wherein the or each barrier layer has a thickness that is at least 13 times as great as the thickness of any one of the quantum well layers.

2. A device as claimed in claim 1 wherein the semiconductor light-emitting device is fabricated in the (Al, Ga, In)N materials system whereby each quantum well layer is an (Al, Ga, In)N layer and the or each barrier layer is an (Al, Ga, In)N layer.

3. A device as claimed in claim 2 wherein each quantum well layer is an InGaN layer.

4. A device as claimed in claim 2 wherein the or each barrier layer is an InGaN layer.

5. A device as claimed in claim 3 wherein the or each barrier layer is an InGaN layer and wherein the indium mole fraction of the or each barrier layer is less than the indium mole fraction of each quantum well layer.

6. A device as claimed in claim 2 wherein the or each barrier layer is a GaN layer.

7. A device as claimed in claim 1 wherein the or each barrier layer has a thickness that is up to 30 times as great as the thickness of any one of quantum well layers.

8. A device as claimed in claim 1 wherein each quantum well layer has a thickness of greater than 1 nm.

9. A device as claimed in claim 1 wherein each quantum well layer has a thickness of less than 20 nm.

10. A device as claimed in claim 1 wherein the or each barrier layer has a thickness of greater than 8 nm.

11. A device as claimed in claim 1 wherein the or each barrier layer has a thickness of less than 50 nm.

12. A device as claimed in claim 1 wherein each quantum well layer is doped.

13. A device as claimed in claim 1 wherein the or each barrier layer is doped.

14. A device as claimed in claim 1 and comprising a semiconductor laser device.

15. A device as claimed in claim 1 and comprising a semiconductor light-emitting diode.

16. A method of fabricating a semiconductor light-emitting device in a nitride materials system, the method comprising the steps of:
a) growing a first quantum well layer;
b) growing a first barrier layer over the first quantum well layer; and
c) growing a second quantum well layer over the first barrier layer;
wherein the first barrier layer has a thickness that is at least 13 times as great as the thickness of any one of the quantum well layers.

17. A method as claimed in claim 16 and further comprising:
d) growing a second barrier layer over the second quantum well layer; and
e) growing a third quantum well layer over the second barrier layer;
wherein the second barrier layer has a thickness that is at least 13 times as great as the thickness of any one of the quantum well layers.

18. A method as claimed in claim 16 and comprising annealing the first barrier layer before step (c) of growing the second quantum well layer.

19. A method as claimed in claim 16 and comprising annealing the second barrier layer before step (e) of growing the third quantum well layer.
